(19) United States
(12) Patent Application Publication
(10) Pub. No.: US 2012/0229002 A1
(43) Pub. Date: Sep. 13, 2012

(54) PIEZOELECTRIC VIBRATING PIECE AND PIEZOELECTRIC DEVICE

(75) Inventor: TAKEHIRO TAKAHASHI, SAITAMA (JP)

(73) Assignee: NIHON DEMPA KOGYO CO., LTD., TOKYO (JP)

(21) Appl. No.: 13/411,625

(22) Filed: Mar. 4, 2012

(30) Foreign Application Priority Data
Mar. 7, 2011 (JP) 2011-049169

(51) Int. Cl. H01L 41/047; H01L 41/22; H01L 41/053

(52) U.S. Cl. 310/344; 310/366; 29/25.35

(57) ABSTRACT

A piezoelectric vibrating piece and a piezoelectric device are provided, in which the deterioration of the vibrating characteristics of a vibrating portion is prevented. The piezoelectric vibrating piece comprises a rectangular-shaped first surface having a long side and a short side; a second surface opposing the first surface; and side surfaces, connecting the first surface and the second surface. The piezoelectric vibrating piece further comprises a first excitation electrode formed on a central part of the first surface; a first extraction electrode extracted from the first excitation electrode to an outer peripheral portion of the second surface via only the side surface at the short side; a second excitation electrode formed on the second surface opposite to the first excitation electrode; and a second extraction electrode extracted from the second excitation electrode to the outer peripheral portion of the second surface.

### CROSS-REFERENCE TO RELATED APPLICATIONS

This application claims the priority benefit of Japan application serial no. 2011-049169, filed on Mar. 7, 2011. The entirety of the above-mentioned patent application is hereby incorporated by reference herein and made a part of this specification.

### TECHNICAL FIELD

The present invention relates to a piezoelectric vibrating piece and a piezoelectric device, and particularly to an electrode shape of an extraction electrode.

### BACKGROUND

As disclosed in Patent Document 1 and Patent Document 2, a conventional piezoelectric device generally consists of a ceramic package and a lid for sealing the package. Additionally, the package consists of a box-shaped body with opening on one surface. A piezoelectric vibrating piece in thickness-shear vibration, such as an AT-cut, is disposed in an inner part of the package. A pair of supporting body to support the piezoelectric vibrating piece is disposed on one side of a bottom surface of the inner part of the package. Furthermore, an electrode conducting with an excitation electrode of the piezoelectric vibrating piece through a conductive adhesive is formed on the pair of the supporting body. An outer peripheral edge portion of the plate-shaped lid is bonded with an opening surface of the package, so as to hermetically seal the inner part of the package.

Generally, the piezoelectric vibrating piece of thickness-shear vibration is configured such that a pair of the excitation electrodes is formed opposite to each other on front and back surfaces of the piezoelectric vibrating piece, and an alternating voltage is applied to the excitation electrodes. The excitation electrodes, connection electrodes for conducting the excitation electrodes with external electrodes (electrodes formed on the supporting body) and extraction electrodes for conducting the excitation electrodes to the connection electrodes are formed on both principal planes of the piezoelectric vibrating piece. With regard to the extraction electrode disclosed in Patent Document 1, in order that any of the front or the rear surface of the piezoelectric vibrating piece to able to connect to the supporting body at two locations of the package, the extraction electrode on the front surface is formed on the back surface via a side surface at a short side of the piezoelectric vibrating piece, and the extraction electrode on the back surface is also formed on the front surface via the side surface at the short side of the piezoelectric vibrating piece. With regard to the extraction electrode disclosed in Patent Document 2, the extraction electrode is introduced to the side surface of the piezoelectric vibrating piece at the side near the outer peripheral edge end portion at a long side of the piezoelectric vibrating piece and is formed on the side surface at the other short side of the piezoelectric vibrating piece via the side surface of the piezoelectric vibrating piece therefrom.

Patent Document 1: JP Patent Publication No. 2007-174630

Patent Document 2: JP Patent Publication No. 2006-157554

However, when the extraction electrode with large area is formed on the side surface connecting the front surface and the rear surface, vibration characteristics of the vibrating portion may worsen due to the influence of an electric field of the extraction electrode formed on the side surface. In addition, when an electrode is formed on a region near the front and rear surfaces and the side surface, an extra electrostatic capacitance will be produced on the piezoelectric vibrating piece.

### SUMMARY

In the present invention, an extraction electrode on a rear surface is formed without being extracted to a front surface and an extraction electrode extracted from the front surface to the rear surface is formed without being extracted to a side surface at a long side of a piezoelectric vibrating piece. Hereby, it is an object of the present invention to provide a piezoelectric vibrating piece and a piezoelectric device, wherein one surface, i.e., the rear surface, of the piezoelectric vibrating piece is placed in a package, so that vibration characteristics of the vibrating portion are not being further degraded.

According to the first aspect of the invention, the invention provides a piezoelectric vibrating piece, comprising a first surface in rectangular shape, including a long side and a short side; a second surface opposite the first surface; side surfaces connecting the first surface and the second surface. The piezoelectric vibrating piece further comprises a first excitation electrode, formed on a central part of the first surface; a first extraction electrode, extracted from the first excitation electrode to an outer peripheral portion of the second surface via only the side surface at the short side; a second excitation electrode formed on the second surface and opposite to the first excitation electrode; and a second extraction electrode extracted from the second excitation electrode to only the outer peripheral portion of the second surface.

According to the second aspect of the invention, in the piezoelectric vibrating piece described in the first aspect, the first extraction electrode extracted to the outer peripheral portion of the second surface and the second extraction electrode extracted only to the outer peripheral portion of the second surface are disposed along one side of the short sides.

According to the third aspect of the invention, in the piezoelectric vibrating piece described in the first aspect, the first extraction electrode extracted to the outer peripheral portion of the second surface and the second extraction electrode extracted only to the outer peripheral portion of the second surface are respectively disposed on a pair of the short sides.

According to the fourth aspect of the invention, a piezoelectric device is provided. The piezoelectric device comprises a base, wherein the mounting terminals at two locations are formed on a mounting surface and connecting terminals at two locations are formed on a bottom surface opposing the mounting surface, the mounting terminals at two locations and the connecting terminals at two locations are being conducted, and a lid covering the bottom surface of the base. The piezoelectric vibrating piece described in any one of the first aspect to the third aspect is placed on the base, and the first extraction electrode and the second extraction electrode are connected to the connecting terminals in two locations respectively.

According to the fifth aspect of the invention, a manufacturing method of a piezoelectric device is provided, and the manufacturing method includes preparing a piezoelectric wafer made of a piezoelectric material, the piezoelectric wafer having a first surface and a second surface opposite the first surface; forming a through-holes, in order to form an outer shape of a plurality of the piezoelectric vibrating pieces and each of which includes a long side and a short side, wherein the through-holes extend from the first surface to the second surface, and are formed at a side surface at the short side of the piezoelectric vibrating piece; forming electrodes on each of the piezoelectric vibrating pieces, wherein forming the electrodes includes: forming a first excitation electrode and a second excitation electrode opposite to each other on the first surface and the second surface, forming a first extraction electrode extracted from the first excitation electrode to an outer peripheral portion of the second surface via only the side surface at the short side, and forming a second extraction electrode extracted only from the second excitation electrode to the outer peripheral portion of the second surface; separating the piezoelectric vibrating pieces one by one from the piezoelectric wafer while holding the piezoelectric vibrating pieces with an arm after the electrodes are formed; and disposing the piezoelectric vibrating piece on a base with the arm in a manner that the first extraction electrode and the second excitation electrode match the connection electrodes formed on the base at two locations.

According to the sixth aspect of the invention, a method of manufacturing a piezoelectric device is provided, and the method comprises: preparing a piezoelectric wafer made of a piezoelectric material, the piezoelectric wafer having a first surface and a second surface opposite the first surface; forming a through-holes, in order to form an outer shape of a plurality of the piezoelectric vibrating pieces, each of which includes a long side and a short side, wherein the through-holes extend from the first surface to the second surface, and are formed at a side surface at the short side of the piezoelectric vibrating piece; forming electrodes on each of the piezoelectric vibrating pieces, wherein forming the electrodes includes: forming a first excitation electrode and a second excitation electrode opposite to each other on the first surface and the second surface, forming a first extraction electrode extracted from the first excitation electrode to an outer peripheral portion of the second surface via only the side surface at the short side, forming a second extraction electrode extracted only from the second excitation electrode to the outer peripheral portion of the second surface; separating the piezoelectric vibrating piece under a condition that the piezoelectric wafer is adhered to a sheet after the electrodes are formed; and removing one of the piezoelectric vibrating pieces from the sheet with an arm, and disposing the removed piezoelectric vibrating piece on a base in a manner that the first extraction electrode and the second excitation electrode match the connection electrodes formed on the base at two locations.

According to the seventh aspect of the invention, in the method of manufacturing the piezoelectric device described in the fifth and the sixth aspects, the method further comprises preparing a base wafer, having a plurality of the bases; preparing a lid wafer, having a plurality of the lids, to seal the bases; and bonding the lid wafer to the base wafer after the step of disposing.

According to the piezoelectric vibrating piece and the piezoelectric device of the present invention, the manufacturing cost can be reduced, and the CI value can be prevented from deteriorating.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is an explosive perspective view of a first piezoelectric device 100.

FIG. 2 is an explosive perspective view along the line A-A of FIG. 1.

FIG. 3 is an unfolded drawing of a quartz-crystal vibrating piece 20.

FIG. 4 is a flowchart illustrating manufacturing steps of the first piezoelectric device 100.

FIG. 5 is a top view of a crystal wafer 20W.

FIG. 6 is a top view of a lid wafer 10W.

FIG. 7 is a top view of a base wafer 30W.

FIG. 8A is a diagram illustrating one crystal vibrating piece 20 in the crystal wafer 20W.

FIG. 8B is a cross-section along the line B-B of FIG. 8A.

FIG. 9 is an explosive perspective view of a second piezoelectric device 110.

FIG. 10 is an explosive perspective view along the line C-C of FIG. 9.

FIG. 11 is a net diagram of a crystal vibrating piece 25.

### DETAILED DESCRIPTION OF DISCLOSED EMBODIMENTS

Preferred embodiments of the present invention are described in more detail below referring to the accompanying drawings. The claims of the invention should not be read as limited to those embodiments unless especially stated to limit the invention in the following description.

In the first embodiment and the second embodiment, an AT-cut crystal vibrating piece is used as a piezoelectric vibrating piece. A principal plane of the crystal vibrating piece is inclined by 35°15′ from a Z-axis to a Y-axis with an x-axis as a center, with respect to Y-axis of the crystal axis (X Y Z) of an artificial quartz crystal. A piezoelectric device 100 described in the following embodiments assumes that a long side direction is a y-axis direction, a short side direction is an x-axis direction and a vertical direction is a z-axis direction. Similarly, the same axis directions are used in a lid, a base and the AT-cut crystal vibrating piece. Therefore, the long side direction, the short side direction and the vertical direction are explained as the y-axis direction, the x-axis direction and the z-axis direction respectively.

### First Embodiment

### <Structure of a First Piezoelectric Device 100>

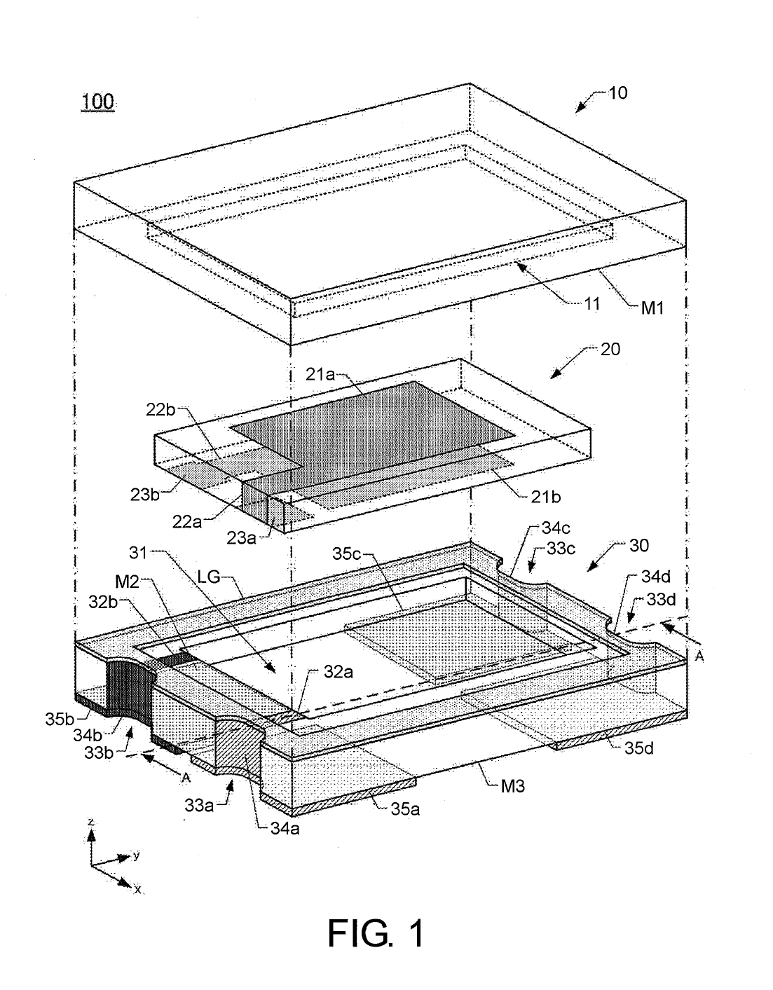

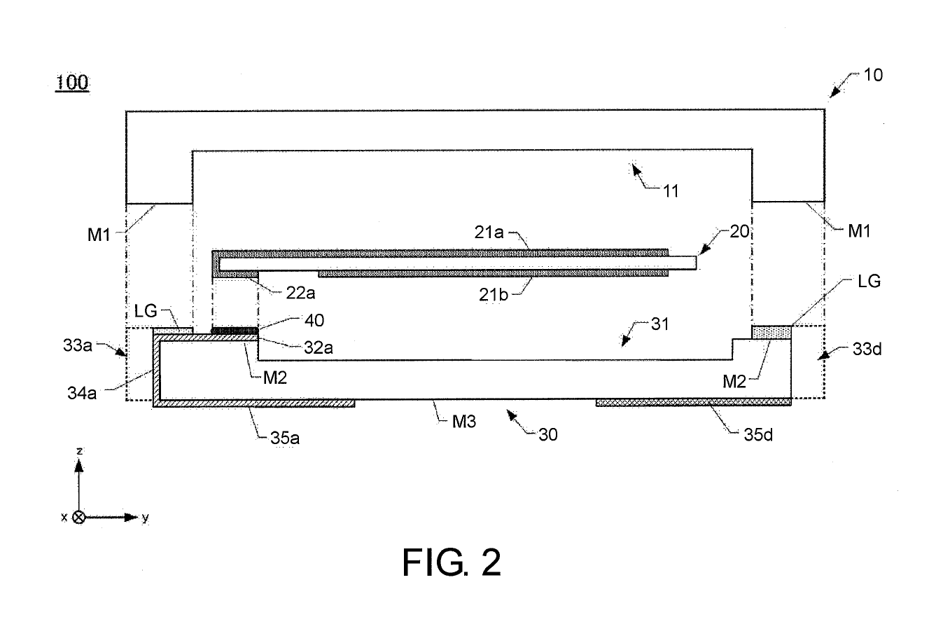

The entire structure of a first piezoelectric device 100 is described with reference to FIG. 1 and FIG. 2. FIG. 1 is an explosive perspective view of the first piezoelectric device 100, and FIG. 2 is an explosive perspective view along the line A-A of FIG. 1. Besides, low melting-point glass LG, which is a sealing material, is shown as transparent in FIG. 1 in order to be able to view an entire connection electrode 32. In addition, base side electrodes 34 and external electrodes 35 at four locations of a base 30 are drawn in penetration status in order to understand the positional relationship thereof.

As shown in FIG. 1 and FIG. 2, the first piezoelectric device 100 comprises a lid 10, a crystal vibrating piece 20 and the base 30, sequentially from the upper side (+z side). The lid 10 has a lid concavity 11, the base 30 has a base concavity 31 and the plate-shaped crystal vibrating piece 20 is placed on the base 30.

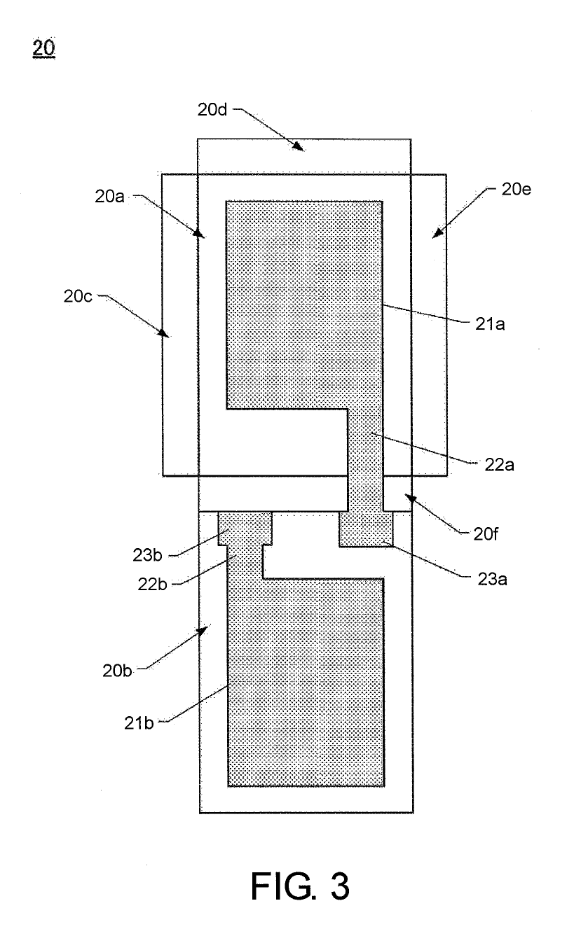

The crystal vibrating piece 20 is formed of an AT-cut crystal material, and a first excitation electrode 21a and a second excitation electrode 21b, which is a pair of excitation electrodes 21, are disposed in opposition on both principal planes near the center. The crystal vibrating piece 20 is a rectangular parallelepiped. FIG. 3 is an unfolded drawing of the crystal vibrating piece 20. The crystal vibrating piece 20 consists of six surfaces, which include a first surface 20a as a principal plane of the upper side (+z side), a second surface 20b as a principal plane of the lower side (−z side) and a third surface 20c to a sixth surface 20f as side surfaces connected with the first surface 20a and the second surface 20b. Besides, the crystal vibrating piece 20 may be a mesa type, an inverted mesa type or a convex type.

The first excitation electrode 21a is formed on the first surface 20a, and the second excitation electrode 21b is formed on the second surface 20b opposite to the first excitation electrode 21a. A first extraction electrode 22a and a second extraction electrode 22b are formed to connect to the first excitation electrode 21a and the second excitation electrode 21b respectively. The first extraction electrode 22a is formed by extracting from the first surface 20a to the second surface 20b via the sixth surface 20f. The second extraction electrode 22b is formed on the second surface 20b by extracting to a side connecting to the sixth surface 20f. An end of the first extraction electrode 22a and an end of the second extraction electrode 22b are respectively formed with a wider width on the second surface 20b respectively as a first connection part 23a and a second connection part 23b. Herein, since the first extraction electrode 22a and the second extraction electrode 22b occupy minimum areas of the first surface 20a, the second surface 20b and the sixth surface 20f, no extra electrostatic capacitance is formed on the piezoelectric vibrating piece.

Herein, the first extraction electrode 22a is not formed on the third surface 20c and the fifth surface 20e. It is because when the extraction electrodes are formed on the third surface 20c and the fifth surface 20e in the long-side direction, an unnecessary vibration is likely to be activated by the extraction electrodes opposite to the short-side direction.

Herein, for example, a chromium layer serving as a base layer is used for the first excitation electrode 21a, the second excitation electrode 21b, the first extraction electrode 22a and the second extraction electrode 22b, and a gold layer is constructed on top of the chromium layer. In addition, a thickness of the chromium layer is, for example, 0.05 μm-0.1 μm, and a thickness of the gold layer is, for example, 0.2 μm-2 μm.

The base 30 is formed of a glass or a piezoelectric material, and a bonding surface M2 is formed around the base concavity 31 on the upper side (the surface of +z side) as shown in FIG. 1 and FIG. 2. In addition, the lower side (the surface of −z side) has a mounting surface M3 surface-mounted to various substrates. Furthermore, base castellations 33a-33d are formed at four locations of the base 30. The base castellations 33a, 33b are formed on the short side at −y side of the base 30 and the base castellations 33c, 33d are formed on the short side at +y side of the base 30.

In addition, base side electrodes 34a-34d are formed on the base castellations 33a-33d respectively. Furthermore, a first connection electrode 32a and a second connection electrode 32b are formed at two locations on the bonding surface M2 of the base 30. Herein, the first connection electrode 32a is electrically connected to the base side electrode 34a, and the second connection electrode 32b is electrically connected to the base side electrode 34b.

Furthermore, external electrodes 35a-35d are formed at four locations on the mounting surface M3 in the base 30. The external electrodes 35a-35d are electrically connected to the base side electrodes 34a-34d respectively.

Herein, the first excitation electrode 21a formed on the crystal vibrating piece 20 is electrically connected via the first extraction electrode 22a, the first connection electrode 32a, the base side electrode 34a and the external electrode 35a. In addition, the second excitation electrode 21b is electrically connected via the second extraction electrode 22b, the second connection electrode 32b, the base side electrode 34b and the external electrode 35b as well. Besides, the first extraction electrode 22a and the first connection electrode 32a is bonded by the first connection part 23a, and the second extraction electrode 22b and the second connection electrode 32b is bonded by the second connection part 23b.

In addition, the external electrode 35c and 35d, which are not used here, are used as earth electrodes. In the present embodiment, the external electrodes 35c and 35d are used as earth electrodes; however, these electrodes also can be used as terminals, which are not electrically connected, to strongly bond the first piezoelectric device 100 to a mounting printed circuit board (not shown).

In the first piezoelectric device 100, a length in the y-axis direction of the crystal vibrating piece 20 is formed the same as or shorter than a length in the y-axis direction of the base concavity 31. Therefore, the first piezoelectric device 100, as shown in FIG. 2, when a conductive adhesive 40 is coated on the first connection electrode 32a and the second connection electrode 32b of the base 30 and the first connection part 23a and the second connection part 23b are placed on the conductive adhesive 40, a cantilever-type first piezoelectric device 100 can be formed, in which one end in the y-axis direction of the crystal vibrating piece 20 is fixed. The conductive adhesive 40 is, for example, a mixture of a resin solvent, such as an epoxy resin, and a powdered metal with conductivity (conductive filler). At the first connection part 23a of the first extraction electrode 22a and the second connection part 23b of the second extraction electrode 22b on the crystal vibrating piece 20, the conductive adhesive 40 can be electrically connected to the first connection electrode 32a and the second connection electrode 32b on the base 30 respectively. Hereby, in the piezoelectric device 100, when an alternating voltage (an electric potential in which positive and negative levels are altered) is applied to the external electrodes 35a, 35b, the alternating voltage is applied to the first excitation electrode 21a and the second excitation electrode 21b. Then, the crystal vibrating piece 20 starts the thickness-shear vibration.

The lid 10 is formed of a glass or a piezoelectric material, and has the lid concavity 11 and a bonding surface M1 formed around the lid concavity 11, in which the lid concavity 11 has a larger area than the base concavity 31 on the xy plane at the lower side (−z side). Besides, the bonding surface M1 on the lid 10 and the bonding surface M2 on the base 30 are bonded together, and a cavity for accommodating the crystal vibrating piece 20 is formed with the lid concavity 11 and the base concavity 31.

Herein, the bonding surface M1 on the lid 10 and the bonding surface M2 on the base 30 are, for example, bonded by a low melting-point glass LG as a sealant (non-conductive adhesive). The low melting-point glass LG includes a lead-free vanadium glass which melts at a temperature of between 350° C. and 410° C. The vanadium glass is added with a binder and a solvent and is in a form of a paste, and adheres to other members after melting followed by solidifying. In addition, the vanadium glass is highly reliable, in terms of water resistance and moisture resistance, for example, and provides superior hermetic adhesion. Furthermore, a thermal expansion coefficient of the vanadium glass can be flexibly controlled by adding filler.

In the lid 10, a length in the long axis direction (y-axis direction) of the lid concavity 11 is longer than a length in the long axis direction of the crystal vibrating piece 20 and a length in the long axis direction of the base concavity 31. In addition, the low melting-point glass LG bonds the lid 10 and the base 30 at the outer side of the bonding surface M2 on the base 30 as shown in FIG. 1 and FIG. 2.

In the present embodiment, the crystal vibrating piece 20 is placed on the bonding surface M2 of the base 30, however, the crystal vibrating piece 20 also can be accommodated in the base concavity 31. Herein, the connection electrode 32 is formed to extend from the base castellation 33 to the bottom surface of the base concavity 31 via the bonding surface M2. Furthermore, in this case, the lid 10 may be plate-shaped without forming the lid concavity 11.

### <Manufacturing Method of the First Piezoelectric Device 100>

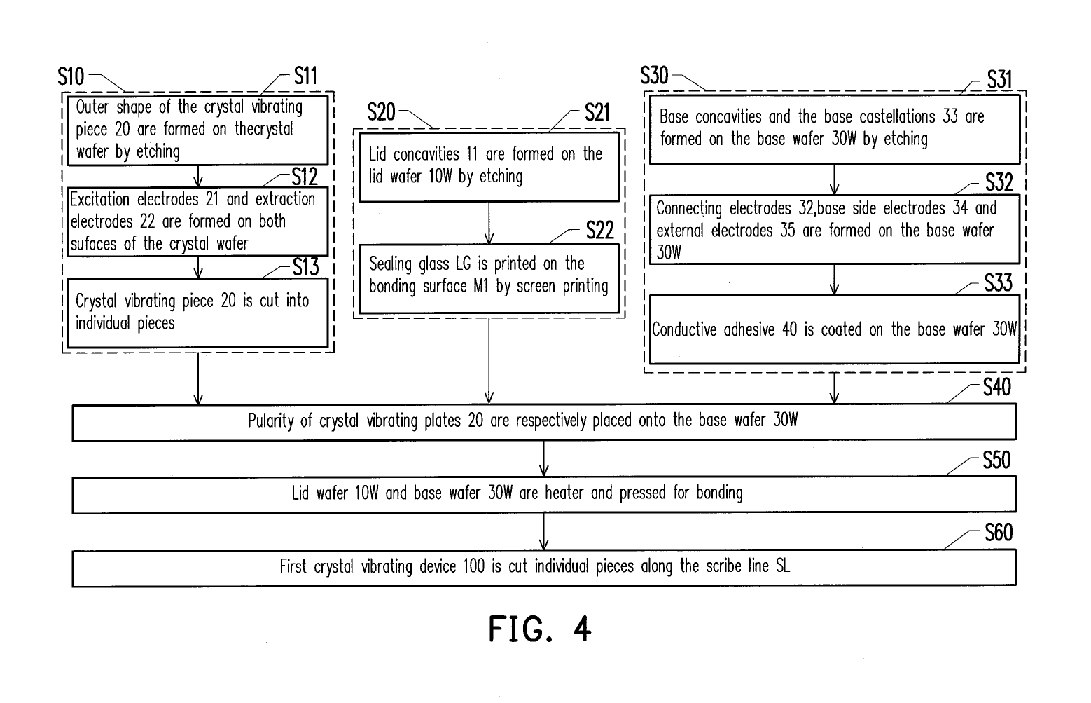

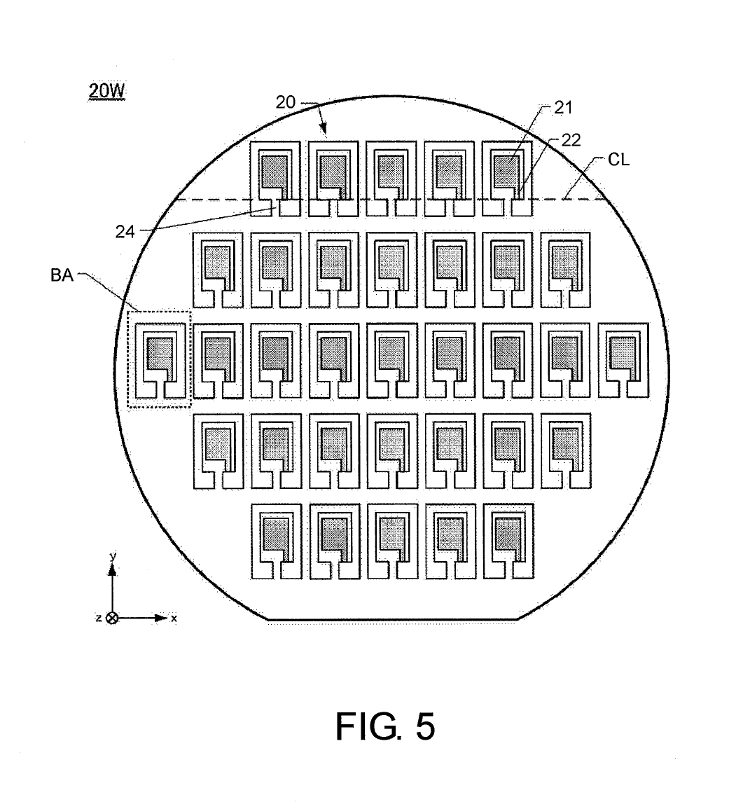

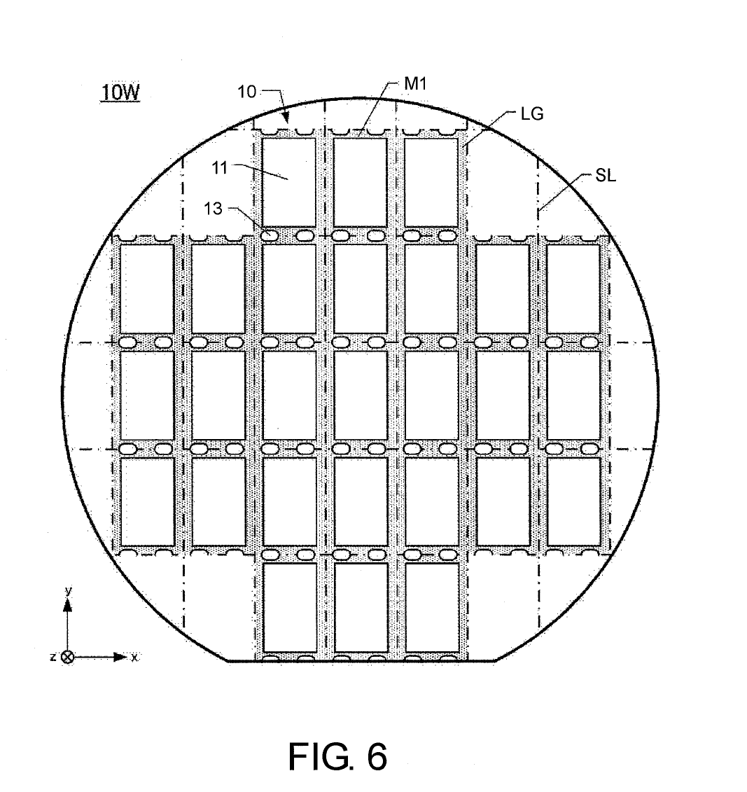

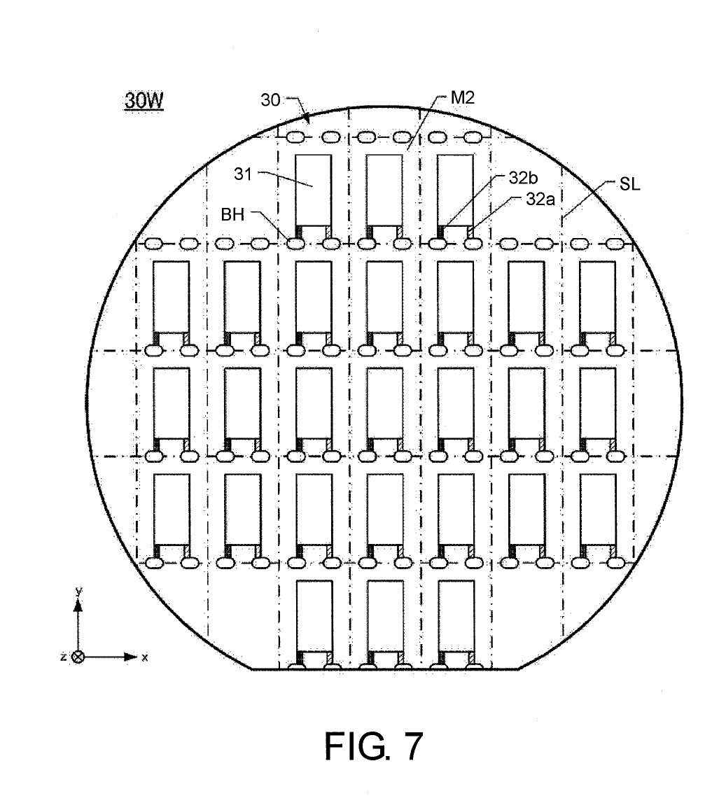

FIG. 4 is a flowchart illustrating manufacturing steps of the first piezoelectric device 100. In FIG. 4, Step S10 of manufacturing the crystal vibrating piece 20, Step S20 of manufacturing the lid 10 and Step S30 of manufacturing the base 30 can be performed concurrently. FIG. 5 is a top view of a crystal wafer 20W capable of manufacturing a plurality of the quartz crystal vibrating pieces 20 at the same time, and FIG. 6 is a top view of a lid wafer 10W capable of manufacturing a plurality of the lids 10 at the same time. FIG. 7 is a top view of a base wafer 30W capable of manufacturing a plurality of the bases 30.

In Step S10, the crystal vibrating pieces 20 are manufactured. Step S10 includes Steps S11-S13.

In Step S11, as shown in FIG. 5, outer shapes of a plurality of crystal vibrating pieces 20 are formed on the uniform crystal wafer 20W by etching. Herein, each crystal vibrating piece 20 is connected to the crystal wafer 20W by a connecting part 24.

In Step S12, the chromium layer and the gold layer are formed by sputtering or vacuum vaporization on a top surface of the crystal wafer 20W, which is the first surface 20a of the crystal vibrating piece 20, and a bottom surface of the crystal wafer 20W, which is the second surface 20b of the crystal vibrating piece 20. Then, a photoresist is uniformly coated on an entire gold layer. Thereafter, by using an exposure device (not shown), patterns of the excitation electrode 21 and extraction electrode 22 drawn on a photomask are exposed onto the crystal wafer 20W. Next, the gold layer exposed by the photoresist is etched. Hereby, as shown in FIG. 4, the excitation electrode 21 and the extraction electrode 22 are formed on the top surface and the bottom surface of the crystal wafer 20W.

In the step S13, the crystal vibrating piece 20 is cut into individual pieces. In the cutting step, a dicing device (not shown) with a laser or a dicing device (not shown) with a cutting blade, etc., is used to cut along a cut line CL (dashed-line) as shown in FIG. 5. Additionally, in the cutting step, the crystal wafer 20W is fixed by a dicing sheet (not shown).

The dicing sheet is formed, for example, of a resin film and an adhesive, and accommodates and seals the excitation electrodes 21 and extraction electrode 22 formed in a convex shape on the crystal vibrating piece 20. A pressure-sensitive adhesive or an adhesive of a photo curing type or a heat generating type can be used as the adhesive. In addition, a gas generating agent, which generates gas by providing light or heat, may be added in the adhesive. In this case, in addition to a reduction of the adhesiveness of the adhesive by light irradiation or heating, an effect is further provided to reduce the adhesiveness since the gas generated by light irradiation or heating shifts at an interface between the crystal vibrating piece 20 and the adhesive, picking up a semiconductor chip becomes easier after dicing.

The dicing sheet can fix the crystal wafer 20W with sufficient adhesion in the cutting step. After dicing the crystal wafer 20W and dividing it into the individual crystal vibrating piece 20, the crystal vibrating pieces 20 are easily removed from the adhesive and the crystal vibrating pieces 20 can certainly be picked up.

A pickup device (not shown) is used to pick up the crystal vibrating piece 20. The pickup device picks up the crystal vibrating piece 20 by placing an adsorption arm to the crystal vibrating piece 20 on the crystal wafer 20W that is adhered to the dicing sheet. The front and back surfaces and the positions on the crystal vibrating pieces 20 are clear after being picked up, so that it can be moved to the base wafer 30W in Step S30 in this status.

In Step S20, the lid 10 is formed. Step S20 includes Step S21 and Step S22.

In Step S21, as shown in FIG. 6, several hundreds to several thousands of the lid concavities 11 are formed on the lid wafer 10W, which is formed of a glass or a piezoelectric material with uniform thickness. The lid concavities 11 are formed in the lid wafer 10W by etching or machining work and the bonding surface M1 is formed around the lid concavities 11.

In Step S22, the low melting-point glass LG is printed on the bonding surface M1 of the lid wafer 10W by screen-printing. Then, by pre-curing the low melting-point glass LG, the low melting-point glass LG film is formed on the bonding surface M1 of the lid wafer 10W. The low melting-point glass film is not formed on a non-bonding area 13 of the lid wafer 10W. The non-bonding area 13 corresponds to a base through-hole BH (see FIG. 7), which is located at the base castellations 33a-33d formed on the base 30. In the present embodiment, the low melting-point glass LG is formed on the lid 10; however, the low melting-point glass LG also can be formed on the bonding surface M2 of the base 30.

In Step S30, the base 30 is manufactured. Step S30 includes Steps S31-S33.

In Step S31, as shown in FIG. 7, several hundreds to several thousands of the base concavities 31 are formed in the base wafer 30W that is formed of a glass or a piezoelectric material with a uniform thickness. The base concavities 31 are formed by etching or machining work on the base wafer 30W, and the bonding surface M2 is formed around the base concavities 31. At the same time, every two of the base through-holes BH in rounded rectangular shape are formed passing through the base wafer 30W. Herein, when the base through-holes BH in rounded rectangular shape are divided into half, the base castellations 33a-33d are formed (see FIG. 1).

In Step S32, by sputtering or vacuum deposition, the chromium (Cr) layer as a base layer is formed on both surfaces of the base wafer 30W, and the gold (Au) layer is formed on the surface of the chromium (Cr) layer. Then, as shown in FIG. 7, the first connection electrode 32a and the second connection electrode 32b are formed on the bonding surface M2 by etching. At the same time, the base side electrodes 34a-34d are formed on the entire surface of the base through-holes BH.

Additionally, at the same time, the external electrodes 35a, 35b at two locations and the external electrodes 35c, 35d at two locations serving as the earth electrodes (see FIG. 1) are formed on the bottom surface of the base wafer 30W, and are formed together with the external electrode 35, which is formed on the base 30 adjacent to the y-axis.

In Step S33, the conductive adhesive 40 is coated on the bonding surface M2. The conductive adhesive 40 is coated on predetermined positions of the first connection electrode 32a and the second connection electrode 32b.

In Step S40, the individual crystal vibrating piece 20, which is manufactured in Step S10, are placed on the conductive adhesive 40 coated on the base wafer 30W. Herein, the pickup device places the crystal vibrating pieces 20 on the conductive adhesive 40 of the base 30 in a manner that the positions of the first connection part 23a and the second connection part 23b on the crystal vibrating pieces 20 match the positions of the first connection electrode 32a and the second connection electrode 32b formed the bonding surface M2 of the base 30. Several hundreds to several thousands of the crystal vibrating pieces 20 are placed on the base wafer 30W.

In Step S50, the lid wafer 10W is placed on the base wafer 30W where the crystal vibrating pieces 20 are placed, and the lid wafer 10W and the base wafer 30W are bonded. Under the circumstances that the lid wafer 10W and the base wafer 30W overlap at the proper position, the low melting-point glass LG is melted by pressurizing and heating, and the lid wafer 10W and the base wafer 30W are bonded in a hermetically sealed condition to maintain an inert gas or vacuum status.

In Step S60, the lid wafer 10W and the base wafer 30W bonded together are cut into individual units. In the cutting step, the dicing device with the laser or the dicing device with the cutting blade, etc., is used to cut along a scribe line SL depicted in dashed-line as shown in FIG. 6 and FIG. 7, with each first piezoelectric device 100 as a unit. Hereby, several hundreds to several thousands of the first piezoelectric devices 100 are manufactured.

### <Modified Example of the Manufacturing Method of the First Piezoelectric Device 100>

This modified example illustrates that the cutting step by the dicing device in the aforementioned Step S13 is not performed. The other steps are the same as the steps in FIG. 4, and the flowchart of the manufacturing is omitted.

For the crystal wafer 20W in the modified example, there is no Step S13, and the process of adhering by the dicing sheet and cutting by the dicing device are not performed. Therefore, the crystal vibrating pieces 20 are bonded to the connection part 24 (see FIG. 5) and disposed on the crystal wafer 20W.

In Step S40 in FIG. 4, the pickup device holds the crystal vibrating pieces 20 connected to the crystal wafer 20W by the connection part 24, and by separating from the crystal wafer 20W, the crystal vibrating pieces 20 is folded and picked up at the connection part 24. One picked-up crystal vibrating pieces 20 is placed on the conductive adhesive 40 that is coated on the base wafer 30W. At this time, the pickup device places the crystal vibrating piece 20 on the conductive adhesive 40 in the base 30 in a manner that the positions of the first connection part 23a and the second connection part 23b of the crystal vibrating piece 20 and the positions of the first connection electrode 32a and the second connection electrode 32b formed on the bonding surface M 2 of the base 30. Several hundreds to several thousands of the crystal vibrating pieces 20 are placed.

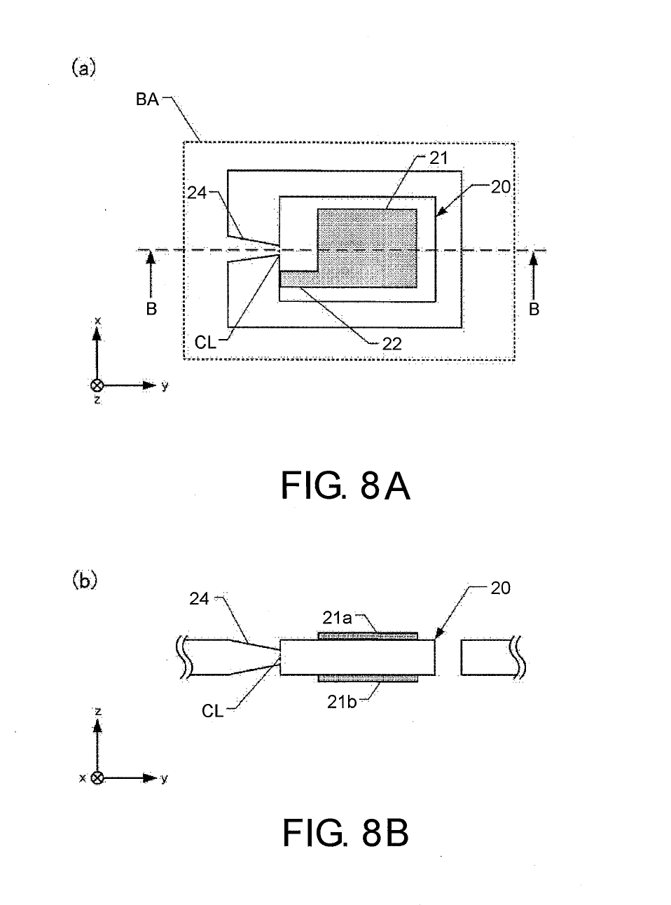

FIG. 8A is a diagram illustrating an area BA of one crystal vibrating piece 20 formed on the crystal wafer 20W in FIG. 5. As shown in the Figure, the connection part 24 is preferably formed in a taper shape towards the cut line CL on the xy surface in order to cut easily at the cut line CL, which the cut line CL is a boundary of the crystal vibrating pieces 20.

FIG. 8B is a cross-section along the line B-B of FIG. 8A. As shown in the Figure, the connection part 24 is preferably formed in a taper shape towards a cut line CL on the yz surface as well in order to cut easily at the cut line CL, in which the cut line CL is a boundary of the crystal vibrating pieces 20.

### Second Embodiment

### <Structure of a Second Piezoelectric Device 110>

In a second piezoelectric device 110 in the present embodiment, compared with the first piezoelectric device 100 described in the first embodiment, the size of the crystal vibrating piece 20 and the arrangement of the electrode are different, and the arrangements of the base concavity 31 and the connection electrode 32 on the base 30 are different. The other parts are the same as the first embodiment, in which the description thereof is omitted, and the same reference numbers are used to refer to the same parts.

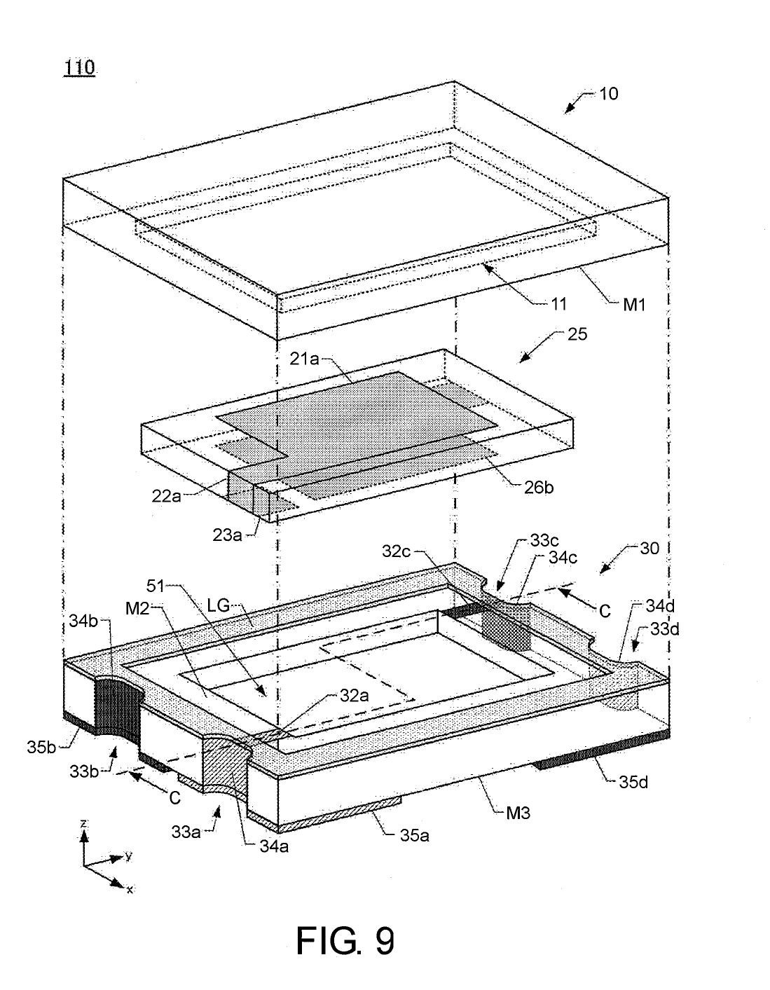

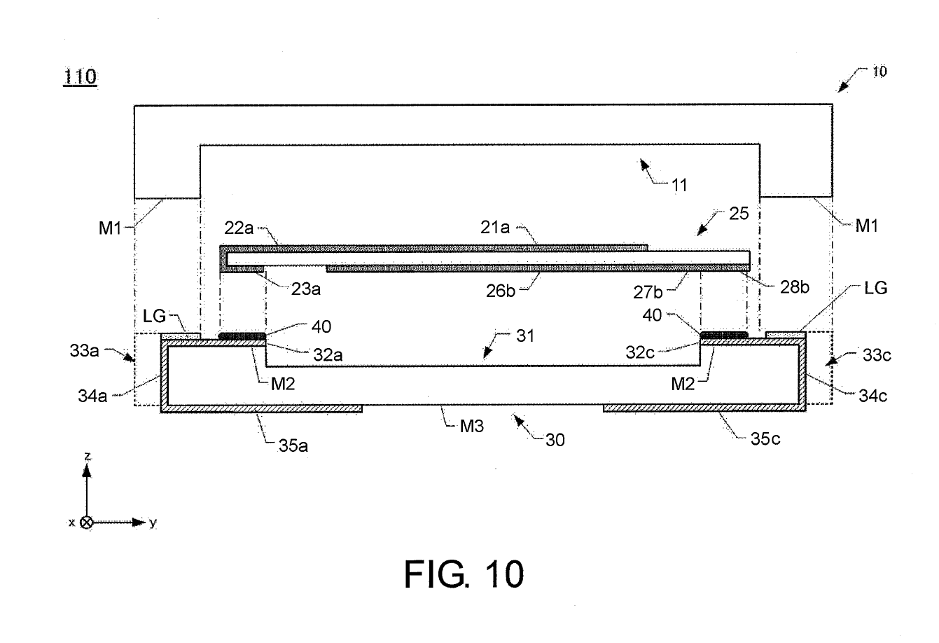

The structure of the second piezoelectric device 110 is described with reference to FIGS. 9, 10 and 11. FIG. 9 is an explosive perspective view of the second piezoelectric device 110. FIG. 10 is an explosive perspective view along the line C-C of FIG. 9. The second piezoelectric device 110 comprises the lid 10, a crystal vibrating piece 25 and the base 30. Besides, the low melting-point glass LG, which is a sealant, is shown as transparent in FIG. 9 in order to be able to view the entire second connection electrode 32b. In addition, base side surface electrodes 34 and external electrodes 35 in four locations in the base 30 are shown as transparent in order to demonstrate the positional relationship thereof, but the external electrode 35 is not shown as transparent.

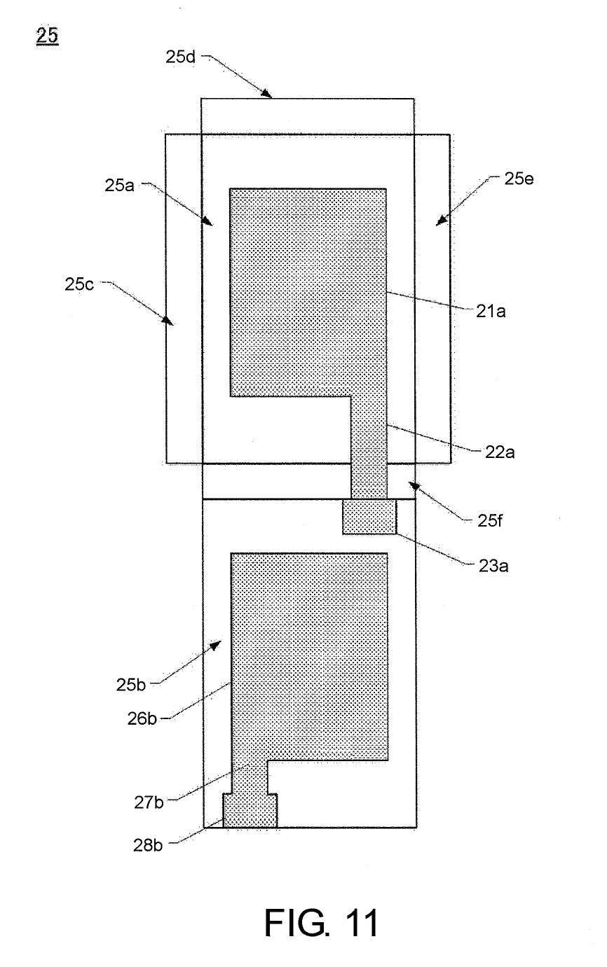

FIG. 11 is a net diagram of the crystal vibrating piece 25. The crystal vibrating piece 25 is made of an AT-cut crystal material, and a pair of the first excitation electrode 21a and the second excitation electrode 21b is disposed in opposition on both principal planes near the center. The crystal vibrating piece 25 is a cuboid and comprises six surfaces, including a first surface 25a as a principal plane of the upper side (+z side), a second surface 25b as a principal plane of the lower side (−z side) and third surface 25c to a sixth surface 25f as a side surface connected with the first surface 25a and the second surface 25b.

The first excitation electrode 21a is formed on the first surface 25a and the second excitation electrode 21b is formed on the second surface 25b. The first extraction electrode 22a and a second extraction electrode 27b are formed in a manner to connect to the first excitation electrode 21a and the second excitation electrode 26b respectively. The first extraction electrode 22a is formed to be extracted from the first surface 25a to the second surface 25b via the sixth surface 25f. The second extraction electrode 27b is formed to be extracted to a side connecting to the fourth surface 25d in the second surface 25b. An end of the first extraction electrode 22a and an end of the second extraction electrode 27b, which are formed on the second surface 25b, are formed with a wide width and serve as the first connection part 23a and a second connection part 28b, respectively. Herein, the first extraction electrode 22a and the second extraction electrode 27b are only formed on the first surface 25a, the second surface 25b and the sixth surface 25f; therefore, there is no extra electrostatic on the piezoelectric vibrating piece.

Herein, the first extraction electrode 22a is not formed on the third surface 25c and the fifth surface 25e. It is because when the extraction electrode is formed on the third surface 25c and the fifth surface 25e in the long-side direction, an unnecessary vibration is likely to be activated by the extraction electrode opposite to the short-side direction.

The first connection electrode 32a and the second connection electrode 32c are formed at two locations on the base 30 (see FIG. 9 and FIG. 10). The first connection electrode 32a and the second connection electrode 32c are disposed at diagonal positions on the bonding surface M2 of the base 30. The first connection electrode 32a is formed near the corner at the short side of −y side, and the second connection electrode 32c is formed near the corner at the short side of +y side. The first connection electrode 32a is electrically connected to the external electrode 35a via the base side electrode 34a, and the second connection electrode 32c is electrically connected to the external electrode 35c via the base side electrode 34c.

A length in the y-axis direction of the base concavity 31 is formed to be shorter than a length in the long side (y-axis direction) of the crystal vibrating piece 25, and both ends in the y-axis direction of the crystal vibrating piece 25 are formed overlapping on the bonding surface M2. That is to say, the bonding surface M2 of the base 30 is formed in a manner that the first connection part 23a on the short side of −y side is bonded with the first connection electrode 32a on the base 30 by the conductive adhesive 40, and the second connection part 23b on the short side of +y side is bonded with the second connection electrode 32c on the base 30 by the conductive adhesive 40.

In the present embodiment, the external electrode 35b and the external electrode 35d are used as earth electrodes; however, they also can be used as terminals, which are not electrically connected, to strongly bond the second piezoelectric device 110 to a mounting printed circuit board (not shown).

The manufacturing method of the second piezoelectric device 110 in the present embodiment can be performed by the same way as the manufacturing method described in the first embodiment. Besides, the crystal vibrating piece 25 with a different shape of the electrode is formed on the crystal wafer 20W, and the base 30 with a different arrangement of the connection electrode 32 is formed on the base wafer 30W.

While the foregoing disclosure refers to certain preferred embodiments of the present invention, it will be apparent to those skilled in the art that various modifications and alterations can be made within the technical scope. For example, the crystal wafer 20W in the present invention can use various piezoelectric single crystal materials, such as a lithium niobate, other than crystal.

What is claimed is:

1. A piezoelectric vibrating piece, comprising:
a first surface in a rectangular shape, the first surface including a pair of long sides and a pair of short sides;
a second surface opposing the first surface;
side surfaces, connecting the first surface and the second surface;
a first excitation electrode, formed on a central part of the first surface;
a first extraction electrode, extracted from the first excitation electrode to an outer peripheral portion of the second surface via only the side surfaces at the pair of short sides;
a second excitation electrode, formed on the second surface, and opposite to the first excitation electrode; and
a second extraction electrode, extracted from the second excitation electrode to only the outer peripheral portion of the second surface.

2. The piezoelectric vibrating piece of claim 1, wherein the first extraction electrode extracted to the outer peripheral portion of the second surface and the second extraction electrode extracted only to the outer peripheral portion of the second surface are disposed along one of the pair of short sides.

3. The piezoelectric vibrating piece of claim 1, wherein the first extraction electrode extracted to the outer peripheral portion of the second surface and the second extraction electrode extracted only to the outer peripheral portion of the second surface are respectively disposed on the pair of short sides.

4. A piezoelectric device, comprising:
a base, including mounting terminals at two locations on a mounting surface and connecting terminals at two locations on the bottom surface opposing the mounting surface, the mounting terminals at two locations are conducted to the connecting terminals at two locations; and
a lid, covering the bottom surface of the base;
wherein the piezoelectric vibrating piece of claim 1 is situated on the base, and the first extraction electrode and the second extraction electrode are connected to the respective connecting terminals.

5. A piezoelectric device, comprising:
a base, including mounting terminals at two locations on a mounting surface and connecting terminals at two locations on the bottom surface opposing the mounting surface, the mounting terminals at two locations are conducted to the connecting terminals at two locations; and
a lid, covering the bottom surface of the base;
wherein the piezoelectric vibrating piece of claim 2 is situated on the base, and the first extraction electrode and the second extraction electrode are connected to the respective connecting terminals.

6. A piezoelectric device, comprising:
a base, including mounting terminals at two locations on a mounting surface and connecting terminals at two locations on the bottom surface opposing the mounting surface, the mounting terminals at two locations are conducted to the connecting terminals at two locations; and
a lid, covering the bottom surface of the base;
wherein the piezoelectric vibrating piece of claim 3 is situated on the base, and the first extraction electrode and the second extraction electrode are connected to the respective connecting terminals.

7. A method of manufacturing a piezoelectric device, comprising:
preparing a piezoelectric wafer made of a piezoelectric material, the piezoelectric wafer having a first surface and a second surface opposing the first surface;
forming through-holes, in order to form an outer shape of a plurality of piezoelectric vibrating pieces, each plurality of piezoelectric vibrating piece includes a long side and a short side, wherein the through-holes extend from the first surface to the second surface and formed on a side surface at the short side of each of the plurality of piezoelectric vibrating piece;
forming electrodes on each of the piezoelectric vibrating piece, wherein the electrodes forming step includes:
forming a first excitation electrode and a second excitation electrode opposing each other on the first surface and the second surface;
forming a first extraction electrode extracted from the first excitation electrode to an outer peripheral portion of the second surface via only the side surface at the short side; and
forming a second extraction electrode extracted only from the second excitation electrode to the outer peripheral portion of the second surface;
separating the plurality of piezoelectric vibrating pieces one by one from the piezoelectric wafer, while holding the plurality of piezoelectric vibrating pieces with an arm after forming the electrodes; and
disposing each piezoelectric vibrating piece on a base with the arm in a manner that the first extraction electrode and the second excitation electrode match the connection electrodes formed on the base at two locations.

8. A method of manufacturing a piezoelectric device, comprising:
preparing a piezoelectric wafer made of a piezoelectric material, the piezoelectric wafer having a first surface and a second surface opposing the first surface;
forming through-holes, in order to form an outer shape of a plurality of piezoelectric vibrating pieces having a long side and a short side, wherein the through-holes extend from the first surface to the second surface, and are formed at a side surface of the short side of the plurality of piezoelectric vibrating pieces;
forming electrodes on the plurality of piezoelectric vibrating pieces, wherein the electrode forming step includes:
forming a first excitation electrode and a second excitation electrode opposing each other on the first surface and the second surface;
forming a first extraction electrode extracted from the first excitation electrode to an outer peripheral portion of the second surface via only the side surface at the short side;
forming a second extraction electrode extracted only from the second excitation electrode to the outer peripheral portion of the second surface;
separating each piezoelectric vibrating piece under a condition that the piezoelectric wafer is adhered on a sheet after the electrodes are formed; and
removing one of the plurality of piezoelectric vibrating pieces from the sheet with an arm, and
disposing the removed one of the plurality of piezoelectric vibrating pieces on a base in a manner that the first extraction electrode and the second excitation electrode match the connection electrodes formed on the base at two locations.

9. The manufacturing method of the piezoelectric device of claim 7, further comprising:
preparing a base wafer having a plurality of bases;
preparing a lid wafer having a plurality of lids, to seal the bases; and
bonding the lid wafer to the base wafer after the step of disposing.

10. The manufacturing method of the piezoelectric device of claim 8, further comprising:
preparing a base wafer having a plurality of bases;
preparing a lid wafer having a plurality of lids, to seal the bases; and
bonding the lid wafer to the base wafer after the step of disposing.
